(19) United States
(12) Patent Application Publication
(10) Pub. No.: US 2026/0147027 A1
(43) Pub. Date: May 28, 2026

(54) TRANSIENT RESPONSE TIME DETERMINATION METHOD, DEVICE, AND STORAGE MEDIUM

(71) Applicant: SHENZHEN INSTITUTES OF ADVANCED TECHNOLOGY, Shenzhen (CN)

(72) Inventors: Ye LI, Shenzhen (CN); Hairong ZHENG, Shenzhen (CN); Xinwei RONG, Shenzhen (CN); Jiasheng WANG, Shenzhen (CN); Jifeng CHEN, Shenzhen (CN); Xing YANG, Shenzhen (CN)

(73) Assignee: SHENZHEN INSTITUTES OF ADVANCED TECHNOLOGY, Shenzhen, GD (CN)

(21) Appl. No.: 19/123,328

(22) PCT Filed: Oct. 12, 2023
(86) PCT No.: PCT/CN2023/124351

§ 371 Date: Apr. 22, 2025

(30) Foreign Application Priority Data
Jul. 5, 2023 (CN) 202310818221.9

(51) Int. Cl. G01R 27/28; G01R 33/36

(52) U.S. Cl. CPC G01R 27/28; G01R 33/3614

(57) ABSTRACT

Provided are a transient response time determination method and apparatus, a device, and a storage medium. The method includes the following: determining the slowest transient response time and the fastest transient response time of the amplitude link, the slowest transient response time and the fastest transient response time of the phase link based on a transient response time of the signal regulating module, a transient response time of signal amplitude processing, a transient response time of signal phase processing, the first transmission time, and the second transmission time; determining an average transient response time of the amplitude link, an average transient response time of the phase link, and a delay time of the delay module based on the slowest transient response time and the fastest transient response time of the amplitude link, and the slowest transient response time and the fastest transient response time of the phase link.

This is a National Stage Application, filed under 35 U.S.C. 371, of International Patent Application No. PCT/CN2023/124351, filed on Oct. 12, 2023, which claims priority to Chinese Patent Application No. 202310818221.9 filed with the China National Intellectual Property Administration (CNIPA) on Jul. 5, 2023, the disclosures of which are incorporated herein by reference in their entireties.

### TECHNICAL FIELD

The present application relates to the technical field of medical magnetic resonance imaging, for example, to a transient response time determination method, a device, and a storage medium.

### BACKGROUND

In magnetic resonance imaging systems, a radio frequency (RF) power amplifier is a commonly used component. The radio frequency power amplifier is typically connected to a radio frequency coil and is used to output an input radio frequency signal to the radio frequency coil after the input radio frequency signal is amplified.

In radio frequency power amplifiers, especially during high-power output, nonlinear correction is required to achieve a constant gain and a constant phase.

### SUMMARY

The present application provides a transient response time determination method and apparatus, a device, and a storage medium.

In a first aspect, an embodiment of the present application provides a transient response time determination method used to determine a transient response time of nonlinear correction of a radio frequency power amplifier in a nonlinear correction system. The nonlinear correction system includes a delay module, a signal regulating module, and a signal amplitude and phase processing module.

An input end of the delay module is connected to a radio frequency input signal, an output end of the delay module is connected to an input end of the signal regulating module, and the delay module is configured to delay and transmit the radio frequency input signal to the signal regulating module. An output end of the signal amplitude and phase processing module is connected to a control end of the signal regulating module, and the signal amplitude and phase processing module is configured to generate a regulation control signal based on at least one of an amplitude or a phase of the radio frequency input signal and at least one of an amplitude or a phase of a radio frequency output signal. An output end of the signal regulating module is connected to an input end of the radio frequency power amplifier, and the signal regulating module is configured to adjust at least one of an amplitude or a phase of a signal output by the delay module based on the regulation control signal. The transient response time determination method includes the following: acquiring a transient response time of the signal regulating module, a transient response time of signal amplitude processing of the signal amplitude and phase processing module, a transient response time of signal phase processing of the signal amplitude and phase processing module, a first transmission time, and a second transmission time; where the first transmission time is a signal delay time on an amplitude link trace from an input end of the signal amplitude and phase processing module to the control end of the signal regulating module, and the second transmission time is a signal delay time on a phase link trace from the input end of the signal amplitude and phase processing module to the control end of the signal regulating module; determining a slowest transient response time of an amplitude link, a fastest transient response time of the amplitude link, a slowest transient response time of the phase link, and a fastest transient response time of the phase link based on the transient response time of the signal regulating module, the transient response time of the signal amplitude processing, the transient response time of the signal phase processing, the first transmission time, and the second transmission time; determining an average transient response time of the amplitude link based on the slowest transient response time of the amplitude link and the fastest transient response time of the amplitude link; determining an average transient response time of the phase link based on the slowest transient response time of the phase link and the fastest transient response time of the phase link; and determining a delay time of the delay module based on the average transient response time of the amplitude link and the average transient response time of the phase link.

In a second aspect, an embodiment of the present application provides a transient response time determination apparatus configured to determine a transient response time of nonlinear correction of a radio frequency power amplifier in a nonlinear correction system. The nonlinear correction system includes a delay module, a signal regulating module, and a signal amplitude and phase processing module. An input end of the delay module is connected to a radio frequency input signal, an output end of the delay module is connected to an input end of the signal regulating module, and the delay module is configured to delay and transmit the radio frequency input signal to the signal regulating module. An output end of the signal amplitude and phase processing module is connected to a control end of the signal regulating module, and the signal amplitude and phase processing module is configured to generate a regulation control signal based on at least one of an amplitude or a phase of the radio frequency input signal and at least one of an amplitude or a phase of a radio frequency output signal. An output end of the signal regulating module is connected to an input end of the radio frequency power amplifier, and the signal regulating module is configured to adjust at least one of an amplitude or a phase of a signal output by the delay module based on the regulation control signal. The transient response time determination apparatus includes a transient response time acquisition module, a slowest and fastest transient response time determination module, an average transient response time determination module for the amplitude link, an average transient response time determination module for the phase link, and a delay time determination module of the delay module. The transient response time acquisition module is configured to acquire a transient response time of the signal regulating module, a transient response time of signal amplitude processing of the signal amplitude and phase processing module, a transient response time of signal phase processing of the signal amplitude and phase processing module, a first transmission time, and a second transmission time; where the first transmission time is a signal delay time on an amplitude link trace from an input end of the signal amplitude and phase processing module to the control end of the signal regulating module, and the second transmission time is a signal delay time on a phase link trace from the input end of the signal amplitude and phase processing module to the control end of the signal regulating module. The slowest and fastest transient response time determination module is configured to determine a slowest transient response time of the amplitude link, a fastest transient response time of the amplitude link, a slowest transient response time of the phase link, and a fastest transient response time of the phase link based on the transient response time of the signal regulating module, the transient response time of the signal amplitude processing, the transient response time of the signal phase processing, the first transmission time, and the second transmission time. The average transient response time determination module for the amplitude link is configured to determine an average transient response time of the amplitude link based on the slowest transient response time of the amplitude link and the fastest transient response time of the amplitude link. The average transient response time determination module for the phase link is configured to determine an average transient response time of the phase link based on the slowest transient response time of the phase link and the fastest transient response time of the phase link. The delay time determination module of the delay module is configured to determine a delay time of the delay module based on the average transient response time of the amplitude link and the average transient response time of the phase link.

In a third aspect, an embodiment of the present application provides an electronic device.

The electronic device includes at least one processor and a memory configured to store at least one program. The at least one program, when executed by the at least one processor, causes the at least one processor to perform the transient response time determination method as described above.

In a fourth aspect, an embodiment of the present application provides a computer-readable storage medium storing a computer program that, when executed by a processor, implements the transient response time determination method as described above.

### BRIEF DESCRIPTION OF DRAWINGS

FIG. 1 is a diagram illustrating the structure of a nonlinear correction system for a radio frequency power amplifier according to an embodiment of the present application.

FIG. 2 is a flowchart of a transient response time determination method according to an embodiment of the present application.

FIG. 3 is a diagram illustrating the structure of another nonlinear correction system for a radio frequency power amplifier according to an embodiment of the present application.

FIG. 4 is a flowchart of another transient response time determination method according to an embodiment of the present application.

FIG. 5 shows an adjustable phase shifter according to an embodiment of the present application.

FIG. 6 is a response curve of the adjustable phase shifter provided in FIG. 5.

FIG. 7 shows another adjustable phase shifter according to an embodiment of the present application.

FIG. 8 is a response curve of the adjustable phase shifter provided in FIG. 7.

FIG. 9 is a diagram illustrating the structure of another nonlinear correction system for a radio frequency power amplifier according to an embodiment of the present application.

FIG. 10 is a flowchart of another transient response time determination method according to an embodiment of the present application.

FIG. 11 is a flowchart of another transient response time determination method according to an embodiment of the present application.

FIG. 12 is a diagram illustrating the structure of another nonlinear correction system for a radio frequency power amplifier according to an embodiment of the present application.

FIG. 13 is a schematic diagram of a transient response time determination apparatus according to an embodiment of the present application.

FIG. 14 is a diagram illustrating the structure of an electronic device according to an embodiment of the present application.

### DETAILED DESCRIPTION

It is to be noted that terms such as “first” and “second” in the description, claims, and drawings of the present application are used to distinguish between similar objects and are not necessarily used to describe a particular order or sequence. It should be understood that the data used in this manner is interchangeable where appropriate so that the embodiments of the present application described herein may also be implemented in a sequence not illustrated or described herein. Additionally, terms “comprising”, “including”, and any other variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

In radio frequency power amplifiers, especially during high-power output, nonlinear correction is required to achieve a constant gain and a constant phase. Related technologies primarily rely on steady-state analysis methods to achieve the nonlinear correction of radio frequency power amplifiers.

However, such steady-state analysis methods overlook the transient response process and cannot determine the transient response time of the amplitude link or the transient response time of the phase link.

The ideal time-domain signal of a radio frequency pulse-modulated signal is a square wave envelope, and the interior of the square wave envelope t contains a carrier wave f0 and a signal with a square wave envelope period T. The frequency-domain signal of the radio frequency pulse-modulated signal follows the Sa(x) function distribution. Due to the limitations of physical devices, the square wave envelope t typically has an edge time (that is, transient response time). The shorter the edge time of the square wave envelope t, the closer the square wave envelope is to an ideal radio frequency pulse-modulated signal, making the edge time an important parameter. In magnetic resonance systems, ultrashort echo time (UTE) sequences impose stringent hardware requirements, with an echo time as short as approximately 70 μs, or even down to 8 us with specialized hardware, which requires the transient response analysis on the radio frequency pulse-modulated signals.

The time-domain discrete sampling function of a radio frequency pulse-modulated signal follows the Sa(x) function distribution. In magnetic resonance systems, the time-domain discrete sampling function is used to achieve parallel acquisition of multi-slice images. An excessively-slow edge time in the transient response of the radio frequency pulse-modulated signal affects the envelope amplitude variation of the sampling function, causing envelope distortion of the radio frequency pulse-modulated signal and resulting in artifacts.

To address the above issues, an embodiment of the present application provides a transient response time determination method, which quantitatively calculates the transient response time of a nonlinear correction system. Based on the transient response time, parameters of the radio frequency power amplifier correction system can be optimized, thereby reducing the transient response time of the nonlinear correction system, reducing the envelope distortion of the radio frequency pulse-modulated signal, and minimizing artifacts.

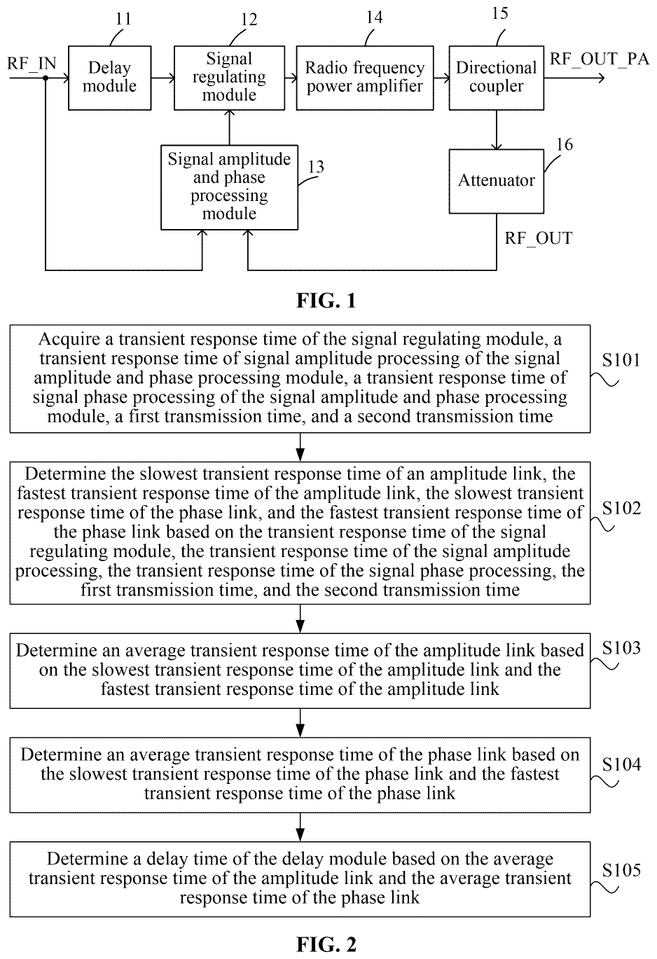

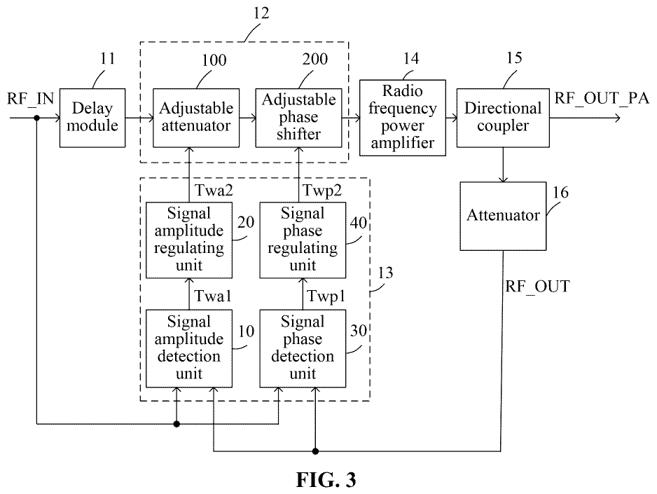

FIG. 1 is a diagram illustrating the structure of a nonlinear correction system for a radio frequency power amplifier according to an embodiment of the present application, and FIG. 2 is a flowchart of a transient response time determination method according to an embodiment of the present application. The transient response time determination method is used to determine the transient response time of nonlinear correction of a radio frequency power amplifier in a nonlinear correction system.

The radio frequency power amplifier mainly amplifies the power of radio frequency signals and is widely used in industries such as wireless communications, radar, and medical magnetic resonance imaging equipment. In magnetic resonance imaging systems, the radio frequency power amplifier is a common component. For radio frequency signals of different power levels, the radio frequency power amplifier exhibits different amplitude amplification capabilities and output phases, presenting nonlinear characteristics.

However, users of magnetic resonance equipment often desire the radio frequency power amplifier to be linear, meaning that for radio frequency signals of different power levels, the radio frequency power amplifier maintains consistent amplification capability, with the same amplitude amplification factor and output phase. Therefore, an additional adjustment apparatus is required to adjust the amplitude amplification factor and output phase of the radio frequency power amplifier to achieve the constant gain and constant phase, which is referred to as a nonlinear correction system.

FIG. 1 is a diagram illustrating the structure of a nonlinear correction system for a radio frequency power amplifier according to an embodiment of the present application. As shown in FIG. 1, the nonlinear correction system includes a delay module 11, a signal regulating module 12, and a signal amplitude and phase processing module 13; a radio frequency input signal RF_IN is coupled to an input end of the delay module 11, an output end of the delay module 11 is connected to an input end of the signal regulating module 12, and the delay module 11 is configured to delay and transmit the radio frequency input signal RF_IN to the signal regulating module 12; an output end of the signal amplitude and phase processing module 13 is connected to a control end of the signal regulating module 12, and the signal amplitude and phase processing module 13 is configured to generate a regulation control signal based on the amplitude and/or phase of the radio frequency input signal RF_IN and the amplitude and/or phase of a radio frequency output signal RF_OUT; an output end of the signal regulating module 12 is connected to an input end of the radio frequency power amplifier 14, and the signal regulating module 12 is configured to adjust the amplitude and/or phase of a signal output by the delay module 11 based on the regulation control signal.

For example, the regulation control signal may be generated based on the amplitude of the radio frequency input signal and the amplitude of the radio frequency output signal; or based on the phase of the radio frequency input signal and the phase of the radio frequency output signal; or based on both the amplitude and phase of the radio frequency input signal and the amplitude and phase of the radio frequency output signal.

For example, an output end of the radio frequency power amplifier 14 is connected to an input end of a directional coupler 15, an output end of the directional coupler 15 is connected to an input end of an attenuator 16, and the directional coupler 15 processes the radio frequency signal output by the radio frequency power amplifier 14 into at least two signal, where one coupling end signal is output to the attenuator 16 while the other through-end signal, a high-power (kW-level) radio frequency output signal RF_OUT_PA, is output to the load. The attenuator 16 is configured to finely adjust attenuation, converting the input coupled signal into a low-power (mW-level) radio frequency output signal RF_OUT. The radio frequency output signal RF_OUT is then fed back to the signal amplitude and phase processing module 13.

In an example, the transient response time determination method may be executed by the nonlinear correction system.

With continued reference to FIG. 2, the transient response time determination method includes the following steps S101 to S105.

In S101, a transient response time of the signal regulating module, a transient response time of signal amplitude processing of the signal amplitude and phase processing module, a transient response time of signal phase processing of the signal amplitude and phase processing module, a first transmission time, and a second transmission time are acquired.

The first transmission time is a signal delay time on an amplitude link trace from an input end of the signal amplitude and phase processing module to the control end of the signal regulating module, and the second transmission time is a signal delay time on a phase link trace from the input end of the signal amplitude and phase processing module to the control end of the signal regulating module.

The signal delay time on a trace refers to the propagation delay time of the signal on a printed circuit board (PCB) trace. The propagation delay time of the signal on the PCB trace is related to the dielectric constant er of the PCB medium. The physical structure of the wiring on the PCB may be classified into a stripline layout and a microstrip layout, with the propagation delay time of the microstrip layout differing from that of the stripline layout.

The propagation delay time for a microstrip layout may be approximately calculated using formula 1.

$$tpd 1 \approx 85 \sqrt{0.475 ε r + 0.67} ( pS / inch ) ; where tpd 1 represents the propagation delay time of the microstrip layout . \qquad Formula 1$$

The propagation delay time for a stripline layout may be approximately calculated using formula 2.

$$tpd 2 \approx 85 \sqrt{ε r} ( pS / inch ) ; where tpd 2 represents the propagation delay time of the stripline layout . \qquad Formula 2$$

For example, for FR4 material with a dielectric constant εr of approximately 4.2, the signal delay time on a surface-layer microstrip trace is about 140 pS/inch, the signal delay time on an inner-layer stripline trace is about 166 pS/inch, and in air, the signal delay time is approximately 85 pS/inch (picoseconds per inch).

The transient response time of the signal regulating module is the edge time of the signal regulating module. The transient response time of signal amplitude processing of the signal amplitude and phase processing module is the sum of the edge times of the units for processing the signal amplitude in the signal amplitude and phase processing module. The transient response time of signal phase processing of the signal amplitude and phase processing module is the sum of the edge times of the units for processing the signal phase in the signal amplitude and phase processing module. The edge times of each component may be acquired from the characteristic curves of the components used in the signal regulating module and the signal amplitude and phase processing module, and data statistics may be performed on the edge time of each component, thus the transient response time acquisition module may acquire the edge time of each component from the statistical data.

Here, the edge time includes a rising edge time and a falling edge time. The rising edge time refers to the time required for the system response curve to rise from 10% of its final value (that is, steady-state value) to 90% of its final value. The embodiments of the present application primarily use the rising edge time to calculate and describe the transient response time, although the falling edge time can also be used to describe the process of a radio frequency pulse signal transitioning from stable to disappearing.

In S102, the slowest transient response time of the amplitude link, the fastest transient response time of the amplitude link, the slowest transient response time of the phase link, and the fastest transient response time of the phase link are determined based on the transient response time of the signal regulating module, the transient response time of the signal amplitude processing, the transient response time of the signal phase processing, the first transmission time, and the second transmission time.

The amplitude link is a link formed by the components for adjusting the signal amplitude in the signal regulating module and the signal amplitude and phase processing module. The phase link is a link formed by the components for adjusting the signal phase in the signal regulating module and the signal amplitude and phase processing module.

Since the transient response time of the amplitude link is related to the modules processing the signal amplitude and the signal delay time on the amplitude link trace, the slowest transient response time and the fastest transient response time of the amplitude link can be determined based on the transient response time of the signal regulating module, the transient response time of the signal amplitude processing, and the first transmission time.

For example, the slowest transient response time of the amplitude link is obtained by summing up the transient response time of the signal regulating module, the transient response time of the signal amplitude processing, and the first transmission time. That is, the slowest transient response time of the amplitude link, calculated based on the rising edge, is that TaMax=TA+TB+Twa. TaMax represents the slowest transient response time of the amplitude link, TA represents the transient response time of the signal regulating module (that is, the rising edge time of the signal regulating module), TB represents the transient response time of signal amplitude processing of the signal amplitude and phase processing module, and Twa represents the first transmission time.

The transient response time of signal amplitude processing on the amplitude link includes a transient response time of amplitude detection and a transient response time of amplitude regulation. The transient response time of amplitude detection is the sum of the edge times of the components for detecting signal amplitude in the signal amplitude and phase processing module. The transient response time of amplitude regulating is the sum of the edge times of the components for regulating signal amplitude in the signal amplitude and phase processing module.

The maximum value among the transient response time of the signal regulating module, the transient response time of amplitude detection, and the transient response time of amplitude regulation is selected. The fastest transient response time of the amplitude link is obtained by summing up the first transmission time and the maximum value among the transient response time of the signal regulating module, the transient response time of amplitude detection, and the transient response time of amplitude regulation. That is, the fastest transient response time of the amplitude link, calculated based on the rising edge, is that TaMin=Max {TA, TB1, TB2}+Twa. TaMin represents the fastest transient response time of the amplitude link, TA represents the transient response time of the signal regulating module (that is, the rising edge time of the signal regulating module), TB1 represents the transient response time of amplitude detection, TB2 represents the transient response time of amplitude regulation, and Twa represents the first transmission time.

Since the transient response time of the phase link is related to the modules for processing the signal phase and the signal delay time on the phase link trace, the slowest transient response time and the fastest transient response time of the phase link can be determined based on the transient response time of the signal regulating module, the transient response time of signal phase processing of the signal amplitude and phase processing module, and the second transmission time.

For example, the slowest transient response time of the phase link is obtained by summing up the transient response time of the signal regulating module, the transient response time of signal phase processing, and the second transmission time. That is, the slowest transient response time of the phase link, calculated based on the rising edge, is that TpMax=TA+TC+Twp. TpMax represents the slowest transient response time of the phase link, TA represents the transient response time of the signal regulating module (that is, the rising edge time of the signal regulating module), TC represents the transient response time of signal phase processing of the signal amplitude and phase processing module, and Twp represents the second transmission time.

The transient response time of signal phase processing on the phase link in the signal amplitude and phase processing module includes a transient response time of phase detection and a transient response time of phase regulation. The transient response time of phase detection is the sum of the edge times of the components for detecting the signal phase in the signal amplitude and phase processing module. The transient response time of phase regulation is the sum of the edge times of the components for regulating the signal phase in the signal amplitude and phase processing module.

The maximum value among the transient response time of the signal regulating module, the transient response time of phase detection, and the transient response time of phase regulation is selected. The fastest transient response time of the phase link is obtained by summing up the second transmission time and the maximum value among the transient response time of the signal regulating module, the transient response time of phase detection, and the transient response time of phase regulation. That is, the fastest transient response time of the phase link, calculated based on the rising edge, is that TpMin=Max {TA, TC1, TC2}+Twp. TpMin represents the fastest transient response time of the phase link, TA represents the transient response time of the signal regulating module (that is, the rising edge time of the signal regulating module), TC1 represents the transient response time of phase detection, TC2 represents the transient response time of phase regulation, and Twp represents the second transmission time.

In S103, an average transient response time of the amplitude link is determined based on the slowest transient response time of the amplitude link and the fastest transient response time of the amplitude link.

For example, the average transient response time of the amplitude link, calculated based on the rising edge, is that TaMed=(TaMax+TaMin)/2. TaMed represents the average transient response time of the amplitude link, TaMax represents the slowest transient response time of the amplitude link, and TaMin represents the fastest transient response time of the amplitude link.

In S104, an average transient response time of the phase link is determined based on the slowest transient response time of the phase link and the fastest transient response time of the phase link.

For example, the average transient response time of the phase link, calculated based on the rising edge, is that TpMed=(TpMax+TpMin)/2. TpMed represents the average transient response time of the phase link, TpMax represents the slowest transient response time of the phase link, and TpMin represents the fastest transient response time of the phase link.

In S105, a delay time of the delay module is determined based on the average transient response time of the amplitude link and the average transient response time of the phase link.

For example, the delay time of the delay module is equal to the sum of the average transient response time of the amplitude link and the average transient response time of the phase link divided by 2. That is, T7Med=(TaMed+TpMed)/2. T7Med represents the delay time of the delay module, TaMed represents the average transient response time of the amplitude link, and TpMed represents the average transient response time of the phase link.

The transient response of the amplitude link and the transient response connected to phase detection are executed in parallel. When the average transient response time of the amplitude link equals the average transient response time of the phase link, the tolerance range of the average transient response time of the amplitude link and the average transient response time of the phase link is minimized, reaching 0. When the average transient response time of the amplitude link equals the average transient response time of the phase link, and the delay time of the delay module equals the sum of the average transient response time of the amplitude link and the average transient response time of the phase link divided by 2, the overall transient response time of the nonlinear correction system is optimal. At this point, the correction can quickly perform tracking and execution, enabling rapid capture and stabilization of the pulsed radio frequency signal, thereby achieving amplitude and phase correction. Moreover, the linearity of the pulsed radio frequency signal is ensured, the detection of multi-slice signals is facilitated, the signal-to-noise ratio is improved, and magnetic resonance artifacts are reduced.

The transient response time determination method provided by the embodiments of the present application, when used in nonlinear correction of a radio frequency power amplifier, determines the slowest transient response time, the fastest transient response time, and the average transient response times of the amplitude link and the phase link of the nonlinear correction system by using the transient response or the rising time of a square wave signal of the signal regulating module and the signal amplitude and phase processing module as the response time of the transient signal. By calculating the average transient response time of the amplitude link and the average transient response time of the phase link, the parameters of the relevant circuits in the nonlinear correction design are optimized, thereby reducing the transient response time of the nonlinear correction system, that is, reducing the edge time of the radio frequency pulse-modulated signal. In this manner, the edge time of the radio frequency pulse-modulated signal does not affect the envelope amplitude of the sampling function, thus reducing the envelope distortion in the radio frequency pulse-modulated signal and minimizing artifacts. In other words, the radio frequency power amplifier formed by the optimized nonlinear correction system can meet the requirements both in the time domain and the frequency domain, making it particularly suitable for generating radio frequency signal waveforms with linear scanning used in magnetic resonance multi-slice parallel imaging. Moreover, the transient response time determination method in the nonlinear correction of the radio frequency power amplifier provides a quantitative indicator for measuring the edge time of the square wave envelope of the radio frequency pulse-modulated signal, which can express the time from initiation to capture of the square wave envelope of the radio frequency pulse-modulated signal.

FIG. 3 is a diagram illustrating the structure of another nonlinear correction system for a radio frequency power amplifier according to an embodiment of the present application. As shown in FIG. 3, in an embodiment, the signal regulating module 12 includes an adjustable attenuator 100 and an adjustable phase shifter 200. An input end of the adjustable attenuator 100 serves as the input end of the signal regulating module 12, an output end of the adjustable attenuator 100 is connected to an input end of the adjustable phase shifter 200, and an output end of the adjustable phase shifter 200 serves as the output end of the signal regulating module 12.

The signal amplitude and phase processing module 13 includes a signal amplitude detection unit 10, a signal amplitude regulating unit 20, a signal phase detection unit 30, and a signal phase regulating unit 40.

The signal amplitude detection unit 10 is configured to detect the amplitude of the radio frequency input signal RF_IN and the amplitude of the radio frequency output signal RF_OUT. The signal amplitude regulating unit 20 is configured to regulate a signal output by the signal amplitude detection unit 10. The signal phase detection unit 30 is configured to detect the phase of the radio frequency input signal RF_IN and the phase of the radio frequency output signal RF_OUT. The signal phase regulating unit 40 is configured to regulate a signal output by the signal phase detection unit 30. The signal amplitude detection unit 10, the signal amplitude regulating unit 20, and the adjustable attenuator 100 form the amplitude link. The signal phase detection unit 30, the signal phase regulating unit 40, and the adjustable phase shifter 200 form the phase link.

For example, the regulation control signal includes a first regulation control signal and a second regulation control signal; an input end of the signal amplitude detection unit 10 and an input end of the signal phase detection unit 30 both serve as the input end of the signal amplitude and phase processing module 13, an output end of the signal amplitude detection unit 10 is connected to an input end of the signal amplitude regulating unit 20, an output end of the signal amplitude regulating unit 20 and an output end of the signal phase regulating unit 40 both serve as the output end of the signal amplitude and phase processing module 13, and an output end of the signal phase detection unit 30 is connected to an input end of the signal phase regulating unit 40.

The signal amplitude detection unit 10 is configured to detect the amplitude of the radio frequency input signal RF_IN and the amplitude of the radio frequency output signal RF_OUT to generate an amplitude difference signal. The signal amplitude regulating unit 20 is configured to generate the first regulation control signal based on the amplitude difference signal, and the first regulation control signal is used to adjust the amplitude of the radio frequency input signal RF_IN. The signal phase detection unit 30 is configured to detect the phase of the radio frequency input signal RF_IN and the phase of the radio frequency output signal RF_OUT to generate a phase difference signal. The signal phase regulating unit 40 is configured to generate the second regulation control signal based on the phase difference signal, and the second regulation control signal is used to adjust the phase of the radio frequency input signal RF_IN.

As an implementation, the adjustable attenuator 100 may be of model MAAV-007941 from MACOM, with a rising time Tr and a falling time Tf both equal to 3 ns, so T1tr and T1Tf are both 3 ns.

As an implementation, the adjustable phase shifter 200 may be a voltage-controlled phase shifter, implemented using a varactor diode combined with a 90-degree 3 dB bridge.

As an implementation, the signal amplitude detection unit 10 includes two power detection chips. The model of the power detection chips is AD8310 from Analog Devices (ADI) Inc., the rising edge time Tr of AD8310 is 20 ns, and the falling edge time Tf of AD8310 is 30 ns. The rising edge time and falling edge time of the signal amplitude detection unit 10 represent the transient response time of converting pulsed power to a pulsed voltage.

As an implementation, the signal amplitude regulating unit 20 may use a TL082 operational amplifier whose rising edge time Tr is 500 ns. The signal amplitude regulating unit 20 may also use THS4032 from Texas Instruments (TI). THS4032 is a low-noise high-speed operational amplifier for signal regulation. According to the test curves in the THS4032 datasheet, the rising edge time Tr and falling edge time Tf of THS4032 are both 34 ns.

As an implementation, the signal phase detection unit 30 uses the AD8302 chip from ADI. The rising time Tr and falling time Tf of the transient response of the AD8302 chip both equal to 40 ns. The signal phase regulating unit 40 may use the THS4032 operational amplifier from TI for signal regulation.

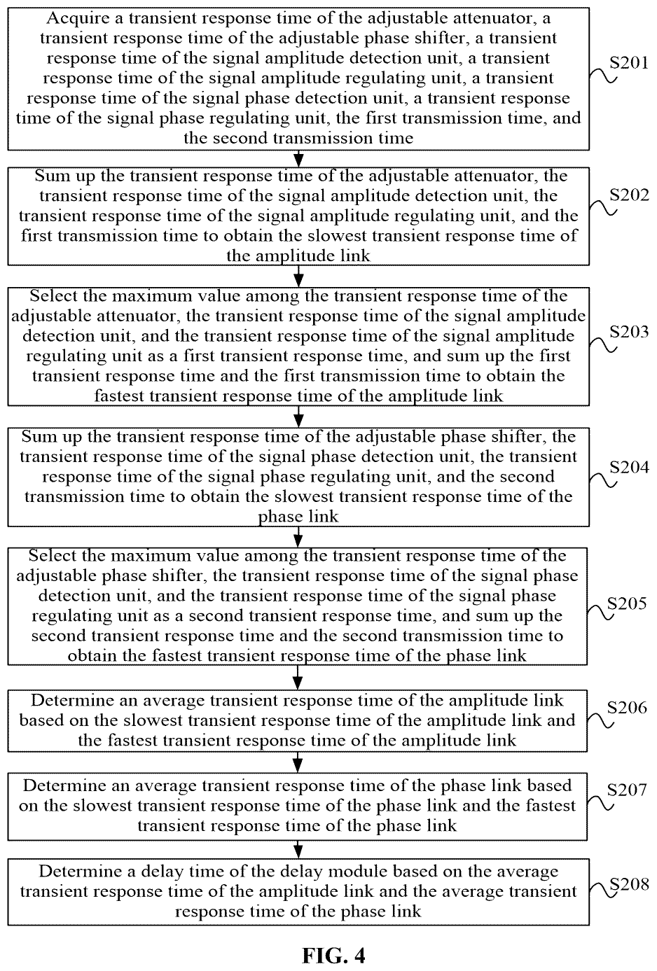

FIG. 4 is a flowchart of another transient response time determination method according to an embodiment of the present application. With reference to FIG. 4, the transient response time determination method includes the following steps S201 to S208.

In S201, a transient response time of the adjustable attenuator, a transient response time of the adjustable phase shifter, a transient response time of the signal amplitude detection unit, a transient response time of the signal amplitude regulating unit, a transient response time of the signal phase detection unit, a transient response time of the signal phase regulating unit, the first transmission time, and the second transmission time are acquired.

With continued reference to FIG. 3, the transient response time of the adjustable attenuator 100 is T1tr, and the transient response time of the signal amplitude regulating unit 20 is T2tr. The signal amplitude detection unit 10 detects the amplitude difference between the radio frequency input signal RF_IN and the fed-back radio frequency output signal RF_OUT and converts the amplitude difference signal into a first low-frequency alternating current signal. The transient response time of the signal amplitude detection unit 10 is T3tr. The transient response time of the adjustable phase shifter 200 is T4tr, and the transient response time of the signal phase regulating unit 40 is T5tr. The signal phase detection unit 30 detects the phase difference between the radio frequency input signal RF_IN and the fed-back radio frequency output signal RF_OUT and converts the phase difference signal into a low-frequency alternating current signal output. The transient response time of the signal phase detection unit 30 is T6tr.

The first transmission time includes a first trace delay time Twa1 and a second trace delay time Twa2. The first trace delay time Twa1 is the signal delay time on the trace from the output end of the signal amplitude detection unit 10 to the signal amplitude regulating unit 20. The second trace delay time Twa2 is the signal delay time on the trace from the signal amplitude regulating unit 20 to the control end of the adjustable attenuator 100.

The second transmission time includes a third trace delay time Twp1 and a fourth trace delay time Twp2. The third trace delay time Twp1 is the signal delay time on the trace from the output end of the signal phase detection unit 30 to the signal phase regulating unit 40. The fourth trace delay time Twp2 is the signal delay time on the trace from the signal phase regulating unit 40 to the control end of the adjustable phase shifter 200.

In S202, the transient response time of the adjustable attenuator, the transient response time of the signal amplitude detection unit, the transient response time of the signal amplitude regulating unit, and the first transmission time are summed up to obtain the slowest transient response time of the amplitude link.

For example, the slowest transient response time TaMax of the amplitude link, calculated based on the rising edge, is equal to T3tr+T2tr+T1tr+Twa1+Twa2.

In S203, the maximum value among the transient response time of the adjustable attenuator, the transient response time of the signal amplitude detection unit, and the transient response time of the signal amplitude regulating unit is selected as a first transient response time, and the first transient response time and the first transmission time are summed up to obtain the fastest transient response time of the amplitude link.

For example, the fastest transient response time TaMin of the amplitude link, calculated based on the rising edge, is equal to Max {T3tr, T2tr, T1tr}+Twa1+Twa2, where Max {T3tr, T2tr, T1tr} is the maximum value among the three, that is, the slowest transient response time among the three.

In S204, the transient response time of the adjustable phase shifter, the transient response time of the signal phase detection unit, the transient response time of the signal phase regulating unit, and the second transmission time are summed up to obtain the slowest transient response time of the phase link.

For example, the slowest transient response time TpMax of the phase link, calculated based on the rising edge, is equal to T4tr+T5tr+T6tr+Twp1+Twp2.

In S205, the maximum value among the transient response time of the adjustable phase shifter, the transient response time of the signal phase detection unit, and the transient response time of the signal phase regulating unit is selected as a second transient response time, and the second transient response time and the second transmission time are summed up to obtain the fastest transient response time of the phase link.

For example, the fastest transient response time TpMin of the phase link, calculated based on the rising edge, is equal to Max {T4tr, T5tr, T6tr}+Twp1+Twp2, where Max {T4tr, T5tr, T6tr} is the maximum value among the three, that is, the slowest transient response time among the three.

In S206, an average transient response time of the amplitude link is determined based on the slowest transient response time of the amplitude link and the fastest transient response time of the amplitude link.

In S207, an average transient response time of the phase link is determined based on the slowest transient response time of the phase link and the fastest transient response time of the phase link.

In S208, a delay time of the delay module is determined based on the average transient response time of the amplitude link and the average transient response time of the phase link.

The transient response time determination method provided by this embodiment can optimize the parameters of the relevant circuits in the nonlinear correction design based on the average transient response time. For example, in the nonlinear correction system before optimization, the adjustable attenuator 100 is of the model MAAV-007941 from MACOM, that is, T1tr is 3 ns.

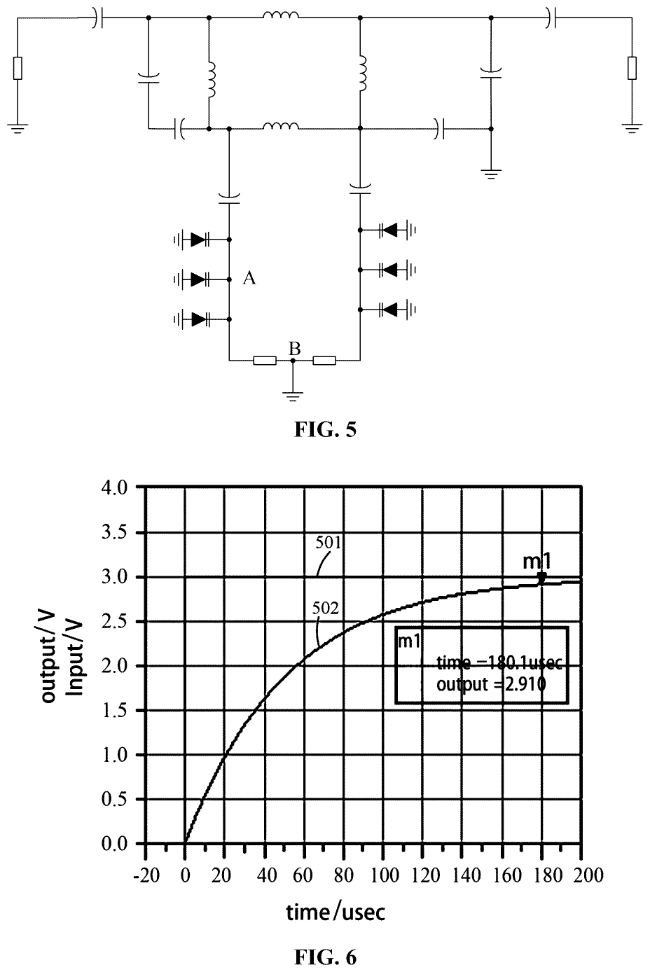

FIG. 5 shows an adjustable phase shifter according to an embodiment of the present application. FIG. 6 is a response curve of the adjustable phase shifter provided in FIG. 5. With reference to FIG. 5 and FIG. 6, the first node A is the output end of the adjustable phase shifter, so the output waveform of the adjustable phase shifter provided in FIG. 5 can be observed from the first node A. The second node B is the input end of the adjustable phase shifter, so the input waveform of the adjustable phase shifter provided in FIG. 5 can be observed from the second node B. In FIG. 6, curve 501 represents the output waveform of the adjustable phase shifter provided in FIG. 5, and curve 502 represents the input waveform of the adjustable phase shifter provided in FIG. 5. As shown in FIG. 6, the rising edge time Tr of the adjustable phase shifter 200 provided in FIG. 5 is 180.1 μs, that is, T4tr is 180.1 μs. The signal amplitude detection unit 10 includes two power detection chips of the model AD8310 from ADI, where the rising edge time Tr is 20 ns, that is, T3tr is 20 ns. The signal amplitude regulating unit 20 uses a TL082 operational amplifier, with the rising edge time Tr of 500 ns, that is, T2tr is 500 ns. The signal phase detection unit 30 uses the AD8302 chip from ADI, with a rising time Tr of the transient response of 40 ns, that is, T6tr is 40 ns. The signal phase regulating unit 40 uses the THS4032 operational amplifier from TI for signal regulating, with a rising time Tr of the transient response of 34 ns, that is, T5tr is 34 ns.

In the nonlinear correction system before optimization, the slowest transient response time TaMax of the amplitude link, calculated based on the rising edge, is that TaMax=T3tr+T2tr+T1tr+Twa1+Twa2=20 ns+500 ns+3 ns+0.8 ns=523.8 ns. The fastest transient response time TaMin of the amplitude link, calculated based on the rising edge, is that TaMin=Max {3 ns, 500 ns, 20 ns}+0.8 ns=500.8 ns. The average transient response time TaMed of the amplitude link, calculated based on the rising edge, is that TaMed=(523.8+500.8)/2=512.3 ns.

The slowest transient response time TpMax of the phase link, calculated based on the rising edge, is that TpMax=T4tr+T5tr+T6tr+Twp1+Twp2=180.1 μs+34 ns+40 ns+0.83 ns=180.17483 μs. The fastest transient response time TpMin of the phase link, calculated based on the rising edge, is that TpMin=Max {180.1 μs, 34 ns, 40 ns}+0.83 ns=180.10083 μs. The average transient response time TpMed of the phase link, calculated based on the rising edge, is that TpMed=(180.17483+180.10083 μs)/2≈180.14 μs.

From the above calculation process, it can be seen that the difference between the average transient response time of the amplitude link and the average transient response time of the phase link is too large. For a radio frequency short pulse of 100 μs, an excessively large difference between the average transient response time of the amplitude link and the average transient response time of the phase link severely affects the capture time of the entire nonlinear correction system, resulting in excessive phase errors in the radio frequency short pulse.

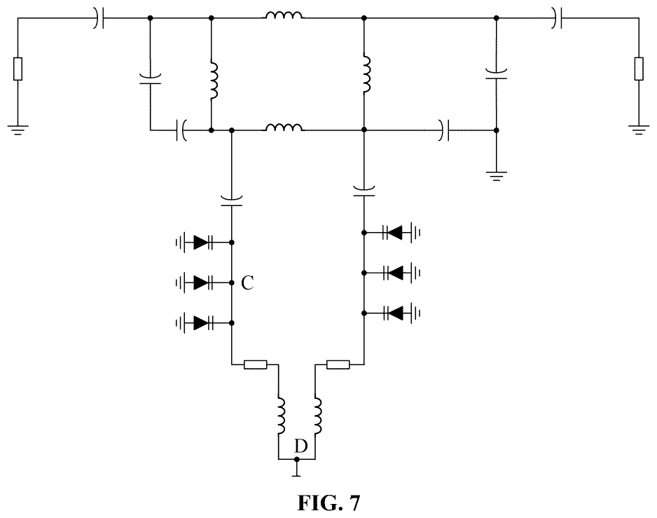

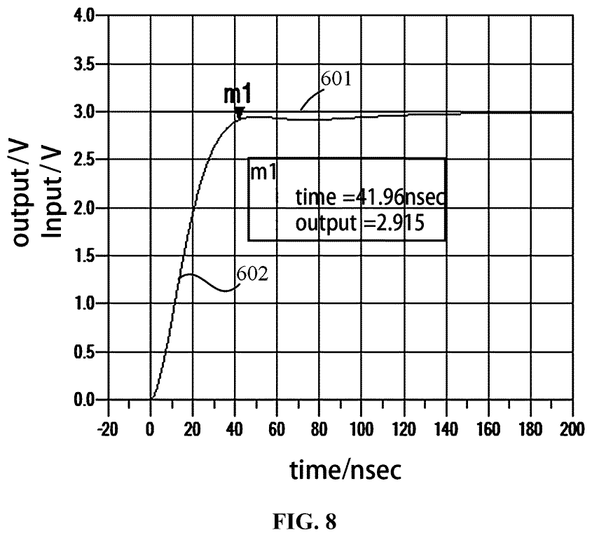

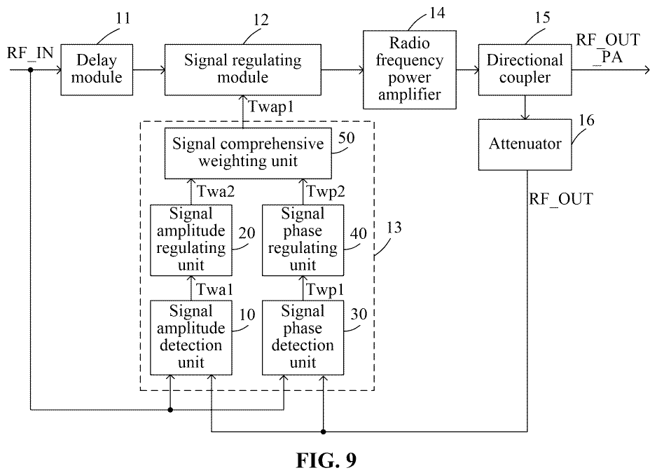

In the optimized nonlinear correction system, the adjustable attenuator 100 is of the model MAAV-007941 from MACOM, that is, T1tr is 3 ns. FIG. 7 shows another adjustable phase shifter according to an embodiment of the present application. FIG. 8 is a response curve of the adjustable phase shifter provided in FIG. 7. With reference to FIG. 7 and FIG. 8, the third node C is the output end of the control signal of the adjustable phase shifter, so the output waveform of the adjustable phase shifter provided in FIG. 7 can be observed from the third node C. The fourth node D is the input end of the control signal of the adjustable phase shifter, so the input waveform of the control signal of the adjustable phase shifter provided in FIG. 7 can be observed from the fourth node D. In FIG. 8, curve 601 represents the output waveform of the control signal of the adjustable phase shifter provided in FIG. 7, and curve 602 represents the input waveform of the control signal of the adjustable phase shifter provided in FIG. 7. As shown in FIG. 8, the rising edge time Tr of the adjustable phase shifter 200 provided in FIG. 7 is 42 ns, that is, T4tr is 42 ns. The signal amplitude detection unit 10 includes two power detection chips of the model AD8310 from ADI, and the rising edge time Tr of AD8310 is 20 ns, that is, T3tr is 20 ns. The signal amplitude regulating unit 20 uses THS4032 from TI, with a rising edge time Tr of 34 ns, that is, T2tr is 34 ns. The signal phase detection unit 30 uses the AD8302 chip from ADI, with a rising time Tr of 40 ns, that is, T6tr is 40 ns. The signal phase regulating unit 40 uses the THS4032 operational amplifier from TI for signal regulation, with a rising time Tr of 34 ns, that is, T5tr is 34 ns.

In the optimized nonlinear correction system for the radio frequency power amplifier, the slowest transient response time, the fastest transient response time, and the average transient response time of the amplitude link are calculated as follows:

The slowest transient response time of the amplitude link is that TaMax=3 ns+34 ns+20 ns+0.8 ns=57.8 ns. The fastest transient response time of the amplitude link is that TaMin=Max {3 ns, 34 ns, 20 ns}+0.8 ns=34.8 ns. The average transient response time of the amplitude link is that TaMed=(57.8+34.8)/2=46.3 ns. The slowest transient response time, the fastest transient response time, and the average transient response time of the phase link in the optimized system are calculated as follows: The slowest transient response time of the phase link is that TpMax=42 ns+34 ns+40 ns+0.83 ns=116.8 ns. The fastest transient response time of the phase link is that TpMin=Min {42 ns+34 ns+40 ns}+0.83 ns=42.8 ns. The average transient response time of the phase link is that TpMed=(116.8+42.8)/2=79.8 ns. The delay time of the delay module is that T7Med=(46.3+79.8)/2=63.05 ns=63.1 ns.

From the calculations, it can be seen that for a pulsed radio frequency power amplifier, in the optimized nonlinear correction system, the transient response time of the amplitude link ranges from 34.8 ns to 57.8 ns, with an average transient response time of 46.3 ns; the transient response time of the phase link ranges from 42.8 ns to 116.8 ns, with an average transient response time of 79.8 ns. The delay time of the delay module is 63.1 ns. Thus, the transient response time error of the entire system is appropriate, with an average transient response time error of the amplitude link of 46.3-63.1=−16.8 ns, where the negative sign indicates that the average transient response time of the amplitude link is faster than the delay time of the delay module; and an average transient response time error of the phase link of 79.8-63.1=+16.7 ns, where the positive sign indicates that the average transient response time of the phase link is slower than the delay time of the delay module.

In summary, the transient response time determination method enables optimization of the nonlinear system correction of the radio frequency power amplifier. The average transient response time of the amplitude link is reduced from 512.3 ns before optimization to 46.3 ns after optimization, and the average transient response time of the phase link is reduced from 180.14 μs before optimization to 79.8 ns after optimization. Therefore, the radio frequency power amplifier constituted by the optimized nonlinear correction system can perform power amplification on the radio frequency pulse of 100 μs or even shorter radio frequency pulses.

FIG. 9 is a diagram illustrating the structure of another nonlinear correction system for a radio frequency power amplifier according to an embodiment of the present application. As shown in FIG. 9, in an embodiment, the signal amplitude and phase processing module 13 includes a signal amplitude detection unit 10, a signal amplitude regulating unit 20, a signal phase detection unit 30, a signal phase regulating unit 40, and a signal comprehensive weighting unit 50.

The signal amplitude detection unit 10 is configured to detect the amplitude of the radio frequency input signal RF_IN and the amplitude of the radio frequency output signal RF_OUT. The signal amplitude regulating unit 20 is configured to regulate a signal output by the signal amplitude detection unit 10. The signal phase detection unit 30 is configured to detect the phase of the radio frequency input signal RF_IN and the phase of the radio frequency output signal RF_OUT. The signal phase regulating unit 40 is configured to regulate a signal output by the signal phase detection unit 30. The signal comprehensive weighting unit 50 is configured to further regulate a signal output by the signal amplitude regulating unit 20 and a signal output by the signal phase regulating unit 40.

The signal comprehensive weighting unit 50 can simultaneously control the amplitude and phase of the signal. The signal comprehensive weighting unit 50 may be a predistorter, which may include circuits such as diodes.

The signal amplitude detection unit 10, the signal amplitude regulating unit 20, the signal comprehensive weighting unit 50, and the signal regulating module 12 form the amplitude link. The signal phase detection unit 30, the signal phase regulating unit 40, the signal comprehensive weighting unit 50, and the signal regulating module 12 form the phase link.

For example, an input end of the signal amplitude detection unit 10 and an input end of the signal phase detection unit 30 both serve as the input end of the signal amplitude and phase processing module 13, an output end of the signal amplitude detection unit 10 is connected to an input end of the signal amplitude regulating unit 20, an output end of the signal amplitude regulating unit 20 is connected to a first input end of the signal comprehensive weighting unit 50, an output end of the signal comprehensive weighting unit 50 serves as the output end of the signal amplitude and phase processing module 13, an output end of the signal phase detection unit 30 is connected to an input end of the signal phase regulating unit 40, and an output end of the signal phase regulating unit 40 is connected to a second input end of the signal comprehensive weighting unit 50.

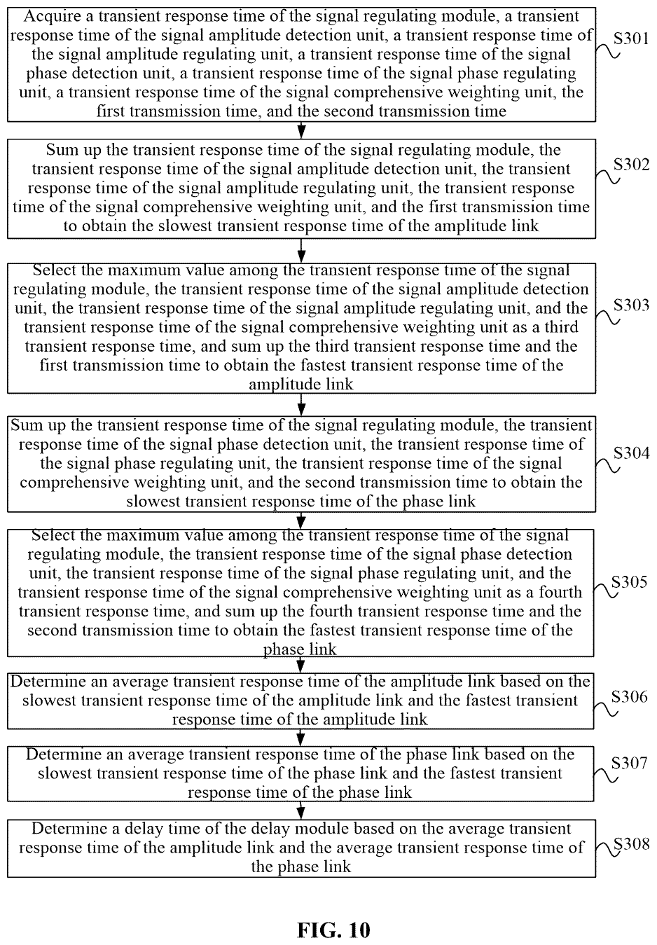

FIG. 10 is a flowchart of another transient response time determination method according to an embodiment of the present application. With reference to FIG. 10, the transient response time determination method includes the following steps S301 to S308.

In S301, the transient response time of the signal regulating module, a transient response time of the signal amplitude detection unit, a transient response time of the signal amplitude regulating unit, a transient response time of the signal phase detection unit, a transient response time of the signal phase regulating unit, a transient response time of the signal comprehensive weighting unit, the first transmission time, and the second transmission time are acquired.

With continued reference to FIG. 9, the transient response time of the signal regulating module 12 is TA, the transient response time of the signal amplitude regulating unit 20 is T2tr, the transient response time of the signal amplitude detection unit 10 is T3tr, the transient response time of the signal phase regulating unit 40 is T5tr, the transient response time of the signal phase detection unit 30 is T6tr, and the transient response time of the signal comprehensive weighting unit 50 is T8tr.

The first transmission time includes a first trace delay time Twa1, a second trace delay time Twa2, and a comprehensive trace time Twap1. The first trace delay time Twa1 is the signal delay time on the trace from the output end of the signal amplitude detection unit 10 to the signal amplitude regulating unit 20. The second trace delay time Twa2 is the signal delay time on the trace from the signal amplitude regulating unit 20 to the input end of the signal comprehensive weighting unit 50. The comprehensive trace time Twap1 is the signal delay time on the trace from the output end of the signal comprehensive weighting unit 50 to the control end of the signal regulating module 12.

The second transmission time includes a third trace delay time Twp1, a fourth trace delay time Twp2, and a comprehensive trace time Twap1. The third trace delay time Twp1 is the signal delay time on the trace from the output end of the signal phase detection unit 30 to the signal phase regulating unit 40. The fourth trace delay time Twp2 is the signal delay time on the trace from the signal phase regulating unit 40 to the input end of the signal comprehensive weighting unit 50. The comprehensive trace time Twap1 is the signal delay time on the trace from the output end of the signal comprehensive weighting unit 50 to the control end of the signal regulating module 12.

In S302, the transient response time of the signal regulating module, the transient response time of the signal amplitude detection unit, the transient response time of the signal amplitude regulating unit, the transient response time of the signal comprehensive weighting unit, and the first transmission time are summed up to obtain the slowest transient response time of the amplitude link.

For example, the slowest transient response time TaMax of the amplitude link, calculated based on the rising edge, is that TaMax=T3tr+T2tr+T8tr+TA+Twa1+Twa2+Twap1.

In S303, the maximum value among the transient response time of the signal regulating module, the transient response time of the signal amplitude detection unit, the transient response time of the signal amplitude regulating unit, and the transient response time of the signal comprehensive weighting unit is selected as a third transient response time, and the third transient response time and the first transmission time are summed up to obtain the fastest transient response time of the amplitude link.

For example, the fastest transient response time TaMin of the amplitude link, calculated based on the rising edge, is that TaMin=Max {T3tr, T2tr, T8tr, TA}+Twa1+Twa2+Twap1, where Max {T3tr, T2tr, T8tr, TA} is the maximum value among the four, that is, the slowest transient response time among the four.

In S304, the transient response time of the signal regulating module, the transient response time of the signal phase detection unit, the transient response time of the signal phase regulating unit, the transient response time of the signal comprehensive weighting unit, and the second transmission time are summed up to obtain the slowest transient response time of the phase link.

For example, the slowest transient response time TpMax of the phase link, calculated based on the rising edge, is that TpMax=TA+T5tr+T6tr+T8tr+Twp1+Twp2+Twap1.

In S305, the maximum value among the transient response time of the signal regulating module, the transient response time of the signal phase detection unit, the transient response time of the signal phase regulating unit, and the transient response time of the signal comprehensive weighting unit is selected as a fourth transient response time, and the fourth transient response time and the second transmission time are summed up to obtain the fastest transient response time of the phase link.

For example, the fastest transient response time TpMin of the phase link, calculated based on the rising edge, is that TpMin=Max {TA, T5tr, T6tr, T8tr}+Twp1+Twp2+Twap1, where Max {TA, T5tr, T6tr, T8tr} is the maximum value among the four, that is, the slowest transient response time among the four.

In S306, an average transient response time of the amplitude link is determined based on the slowest transient response time of the amplitude link and the fastest transient response time of the amplitude link.

In S307, an average transient response time of the phase link is determined based on the slowest transient response time of the phase link and the fastest transient response time of the phase link.

In S308, a delay time of the delay module is determined based on the average transient response time of the amplitude link and the average transient response time of the phase link.

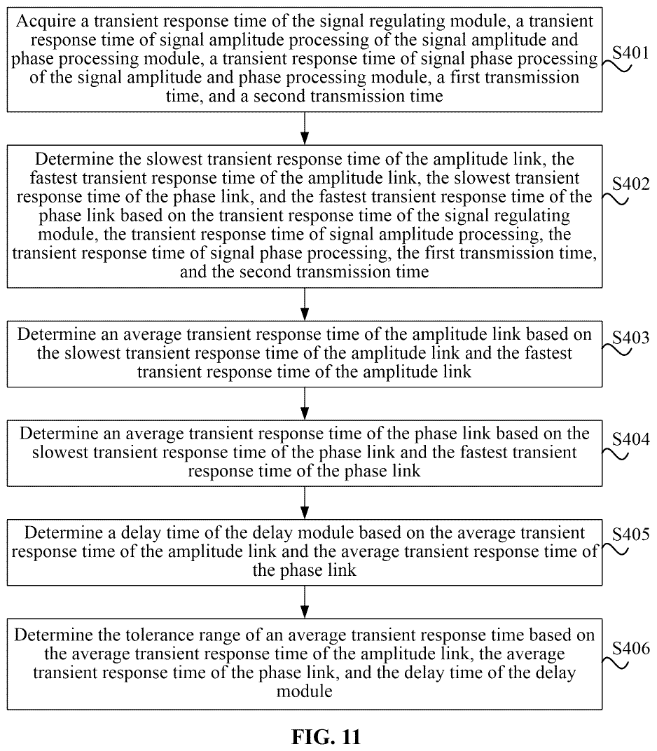

FIG. 11 is a flowchart of another transient response time determination method according to an embodiment of the present application. Based on the above embodiments, with reference to FIG. 11, the transient response time determination method includes the following steps S401 to S406.

In S401, a transient response time of the signal regulating module, a transient response time of signal amplitude processing of the signal amplitude and phase processing module, a transient response time of signal phase processing of the signal amplitude and phase processing module, a first transmission time, and a second transmission time are acquired.

In S402, the slowest transient response time of the amplitude link, the fastest transient response time of the amplitude link, the slowest transient response time of the phase link, and the fastest transient response time of the phase link are determined based on the transient response time of the signal regulating module, the transient response time of signal amplitude processing, the transient response time of signal phase processing, the first transmission time, and the second transmission time.

In S403, an average transient response time of the amplitude link is determined based on the slowest transient response time of the amplitude link and the fastest transient response time of the amplitude link.

In S404, an average transient response time of the phase link is determined based on the slowest transient response time of the phase link and the fastest transient response time of the phase link.

In S405, a delay time of the delay module is determined based on the average transient response time of the amplitude link and the average transient response time of the phase link.

In S406, the tolerance range of an average transient response time is determined based on the average transient response time of the amplitude link, the average transient response time of the phase link, and the delay time of the delay module.

The first boundary value of the tolerance range of the average transient response time is obtained by subtracting the delay time from the average transient response time of the amplitude link. The second boundary value of the tolerance range of the average transient response time is obtained by subtracting the delay time from the average transient response time of the phase link. The first boundary value and the second boundary value are opposite numbers of each other.

For example, the transient response time of the amplitude link ranges from 34.8 ns to 57.8 ns, with an average transient response time of 46.3 ns; the transient response time of the phase link ranges from 42.8 ns to 116.8 ns, with an average transient response time of 79.8 ns. The delay time of the delay module is 63.1 ns.

The first boundary value of the tolerance range of the average transient response time is 46.3−63.1=−16.8 ns, where the negative sign indicates that the average transient response time of the amplitude link is faster than the delay time of the delay module. The second boundary value of the tolerance range of the average transient response time is 79.8−63.1=+16.7 ns, where the positive sign indicates that the average transient response time of the phase link is slower than the delay time of the delay module.

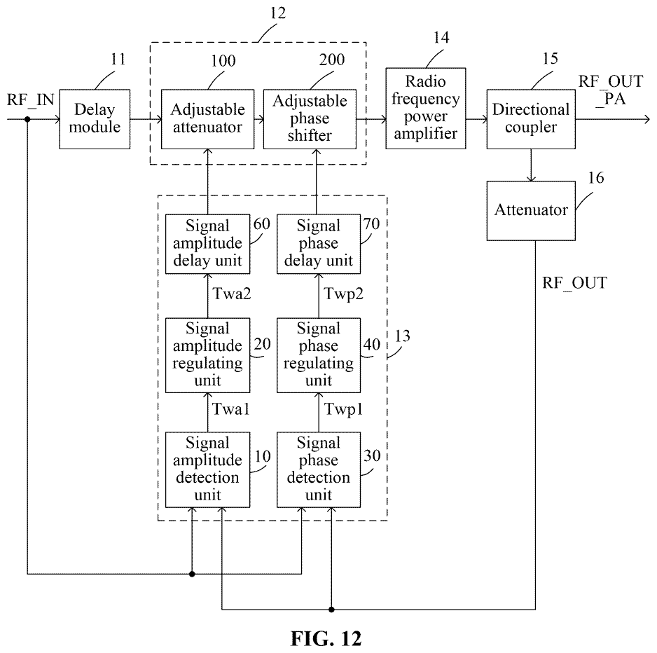

FIG. 12 is a diagram illustrating the structure of another nonlinear correction system for a radio frequency power amplifier according to an embodiment of the present application. With reference to FIG. 12, the nonlinear correction system includes a delay module 11, a signal regulating module 12, and a signal amplitude and phase processing module 13. The signal regulating module 12 includes an adjustable attenuator 100 and an adjustable phase shifter 200. The signal amplitude and phase processing module 13 includes a signal amplitude detection unit 10, a signal amplitude regulating unit 20, a signal phase detection unit 30, a signal phase regulating unit 40, a signal amplitude delay unit 60, and a signal phase delay unit 70.

For example, an input end of the signal amplitude detection unit 10 and an input end of the signal phase detection unit 30 both serve as the input end of the signal amplitude and phase processing module 13, an output end of the signal amplitude detection unit 10 is connected to an input end of the signal amplitude regulating unit 20, an output end of the signal amplitude regulating unit 20 is connected to an input end of the signal amplitude delay unit 60, an output end of the signal amplitude delay unit 60 and an output end of the signal phase delay unit 70 both serve as the output end of the signal amplitude and phase processing module 13, an output end of the signal phase detection unit 30 is connected to an input end of the signal phase regulating unit 40, and an output end of the signal phase regulating unit 40 is connected to an input end of the signal phase delay unit 70.

The transient response time of the adjustable attenuator 100 is T1tr. The transient response time of the signal amplitude regulating unit 20 is T2tr. The transient response time of the signal amplitude detection unit 10 is T3tr. The transient response time of the adjustable phase shifter 200 is T4tr. The transient response time of the signal phase regulating unit 40 is T5tr. The transient response time of the signal phase detection unit 30 is T6tr. The delay time of the delay module is T7tr. The delay time of the signal amplitude delay unit 60 is T9. The delay time of the signal phase delay unit 70 is T10.

The initial values of the delay time T9 of the signal amplitude delay unit 60 and the delay time T10 of the signal phase delay unit 70 are set to 0.

With reference to the calculation formulas of the above embodiments, the average transient response time of the amplitude link, the average transient response time of the phase link, and the delay difference between the average transient response time of the amplitude link and the average transient response time of the phase link are calculated separately. Based on the delay difference between the average transient response time of the amplitude link and the average transient response time of the phase link, the delay time of the corresponding delay unit on the detection link with a longer time is set to 0, and the delay time of the corresponding delay unit on the detection link with a shorter time is set to the delay difference between the two.

For example, the average transient response time of the amplitude link is 46.3 ns (the link with the shorter time), the average transient response time of the phase link is 79.8 ns (the link with the longer time), and the delay difference between the average transient response time of the amplitude link and the average transient response time of the phase link is (79.8-46.3)=33.5 ns. Therefore, at this point, the delay time of the signal amplitude delay unit 60 is set to 33.5 ns, and the delay time of the signal phase delay unit 70 is set to 0 ns. At this time, the average transient response time of the amplitude link, the average transient response time of the phase link, and the delay time of the delay module are all equal, at 79.8 ns, and the tolerance of the nonlinear correction system is 0.

The embodiments of the present application achieve the nonlinear correction function of the radio frequency power amplifier by using the edge time of the transient response to calculate the overall transient response time, calculating the delay time of the delay module using the average transient response times of the amplitude link and the phase link, providing a tolerance range for the average transient response time, and providing a nonlinear correction system with a tolerance range of the average transient response time of 0. Based on the average transient response time, the parameters of the relevant circuits in the nonlinear correction design are optimized, and comparisons are made among components with the same function to reduce the transient response time of the nonlinear correction system, thereby reducing the envelope distortion in the radio frequency pulse-modulated signal and minimizing artifacts.

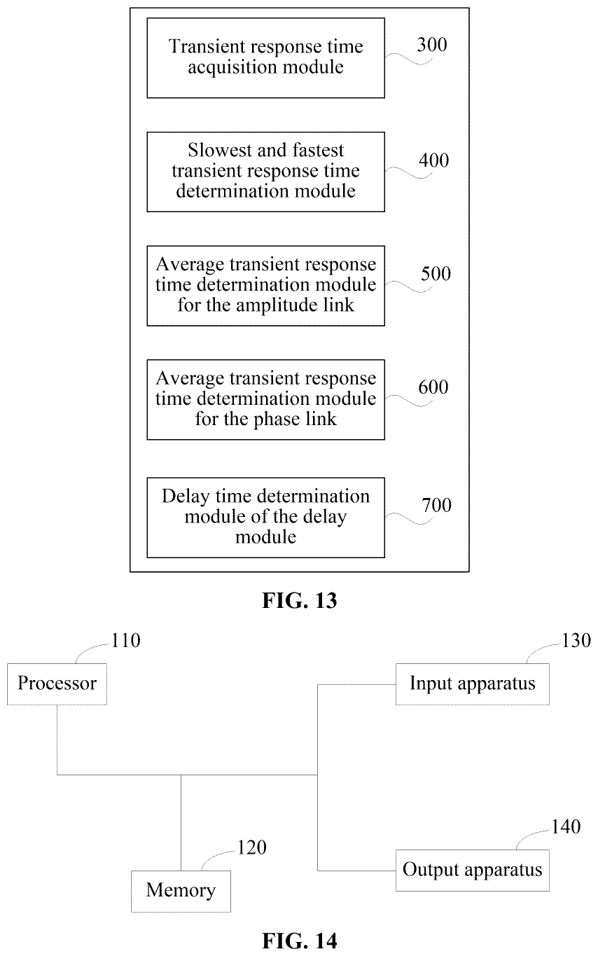

FIG. 13 is a schematic diagram of a transient response time determination apparatus according to an embodiment of the present application. The transient response time determination apparatus is configured to determine a transient response time of nonlinear correction of a radio frequency power amplifier in a nonlinear correction system.

With continued reference to FIG. 1, the nonlinear correction system includes a delay module 11, a signal regulating module 12, and a signal amplitude and phase processing module 13. The radio frequency input signal RF_IN is coupled to an in input end of the delay module 11, an output end of the delay module 11 is connected to an input end of the signal regulating module 12, and the delay module 11 is configured to delay and transmit the radio frequency input signal RF_IN to the signal regulating module 12.

An output end of the signal amplitude and phase processing module 13 is connected to a control end of the signal regulating module 12, and the signal amplitude and phase processing module 13 is configured to generate a regulation control signal based on the amplitude and/or phase of the radio frequency input signal RF_IN and the amplitude and/or phase of a radio frequency output signal RF_OUT. An output end of the signal regulating module 12 is connected to an input end of the radio frequency power amplifier 14, and the signal regulating module 12 is configured to adjust the amplitude and/or phase of a signal output by the delay module 11 based on the regulation control signal.

With reference to FIG. 13, the transient response time determination apparatus includes a transient response time acquisition module 300, a slowest and fastest transient response time determination module 400, an average transient response time determination module for the amplitude link 500, an average transient response time determination module for the phase link 600, and a delay time determination module 700 of the delay module.

The transient response time acquisition module 300 is configured to acquire a transient response time of the signal regulating module, a transient response time of signal amplitude processing of the signal amplitude and phase processing module, a transient response time of signal phase processing of the signal amplitude and phase processing module, a first transmission time, and a second transmission time; where the first transmission time is a signal delay time on an amplitude link trace from an input end of the signal amplitude and phase processing module to the control end of the signal regulating module, and the second transmission time is a signal delay time on a phase link trace from the input end of the signal amplitude and phase processing module to the control end of the signal regulating module.

The slowest and fastest transient response time determination module 400 is configured to determine the slowest transient response time of an amplitude link, the fastest transient response time of the amplitude link, the slowest transient response time of the phase link, and the fastest transient response time of the phase link based on the transient response time of the signal regulating module, the transient response time of the signal amplitude processing, the transient response time of the signal phase processing, the first transmission time, and the second transmission time. The average transient response time determination module for the amplitude link 500 is configured to determine an average transient response time of the amplitude link based on the slowest transient response time of the amplitude link and the fastest transient response time of the amplitude link. The average transient response time determination module for the phase link 600 is configured to determine an average transient response time of the phase link based on the slowest transient response time of the phase link and the fastest transient response time of the phase link. The delay time determination module 700 is configured to determine a delay time of the delay module based on the average transient response time of the amplitude link and the average transient response time of the phase link.

For example, the delay module may be implemented using a delay line, a surface acoustic wave device, a filter composed of inductors, capacitors, and resistors, or a combination thereof.

FIG. 14 is a diagram illustrating the structure of an electronic device according to an embodiment of the present application. As shown in FIG. 14, the electronic device includes one or more processors 110 and a memory 120. FIG. 14 shows one processor 110 by way of example.

The electronic device may also include an input apparatus 130 and an output apparatus 140.

It is understood that the electronic device may not include an input apparatus 130 and an output apparatus 140.

The processor 110, the memory 120, the input apparatus 130, and the output apparatus 140 in the electronic device may be connected via a bus or in other manners, with connection via a bus as an example in FIG. 14.

As a computer-readable storage medium, the memory 120 may be configured to store software programs, computer-executable programs, and modules. The processor 110 runs the software programs, instructions, and modules stored in the memory 120 to perform function applications and data processing, that is, to implement any method in the preceding embodiments.

The memory 120 may include a program storage region and a data storage region, where the program storage region may store an operating system and an application program required by at least one function while the data storage region may store data created according to the use of an electronic device. In addition, the memory may include a volatile memory, such as a random access memory (RAM), and may also include a nonvolatile memory, such as at least one click memory, a flash memory or other nonvolatile solid-state memories.

The memory 120 may be a non-transient computer storage medium or a transient computer storage medium. The non-transient computer storage medium includes, for example, at least one disk memory, a flash memory or another nonvolatile solid-state memory. In some embodiments, the memory 120 optionally includes memories that are remotely disposed relative to the processor 110, and these remote memories may be connected to the electronic device via a network. Examples of such a network may include the Internet, intranets, local area networks, mobile communication networks, and combinations thereof.

The input apparatus 130 may be configured to receive inputted digital or character information and generate key signal input related to user settings and function control of the electronic device. The output apparatus 140 may include display devices such as a display screen.

This embodiment also provides a computer-readable storage medium, which is configured to store a computer program for executing the methods described above.

The storage medium may be non-transitory.

The above method may also exist independently in the form of software, and this embodiment is not limited thereto.

All or part of the procedure processes in the methods of the above embodiments may be implemented by related hardware executed by computer programs. These programs may be stored in a non-transient computer-readable storage medium. During the execution of these programs, the processes in the preceding method embodiments may be implemented. The non-transient computer-readable storage medium may be a magnetic disk, an optical disk, a read-only memory (ROM), or a RAM.

The embodiments of the present application provide a transient response time determination method and apparatus, a device, and a storage medium, offering a quantitative indicator for calculating the transient response time, enabling the determination of the transient response time of the amplitude link and the transient response time of the phase link. Based on the transient response time, the relevant circuits and parameters can be optimized, and comparisons can be made among components with the same function, thereby reducing the transient response time of the nonlinear correction system.

It is to be understood that various forms of processes shown above may be adopted with steps reordered, added, or deleted. For example, the steps described in the present application may be performed in parallel, sequentially, or in different orders, as long as the desired results of the technical solutions of the present application can be achieved, and no limitation is imposed herein.

The specific embodiments described above do not constitute a limitation on the scope of the present application. It is to be understood by those skilled in the art that various modifications, combinations, sub-combinations, and substitutions may be performed according to design requirements and other factors.

What is claimed is:

1. A transient response time determination method, wherein the transient response time determination method is used to determine a transient response time of nonlinear correction of a radio frequency power amplifier in a nonlinear correction system, the nonlinear correction system comprises a delay module, a signal regulating module, and a signal amplitude and phase processing module;
a radio frequency input signal is coupled to an input end of the delay module, an output end of the delay module is connected to an input end of the signal regulating module, and the delay module is configured to delay and transmit the radio frequency input signal to the signal regulating module;
an output end of the signal amplitude and phase processing module is connected to a control end of the signal regulating module, and the signal amplitude and phase processing module is configured to generate a regulation control signal based on at least one of an amplitude or a phase of the radio frequency input signal and at least one of an amplitude or a phase of a radio frequency output signal; and
an output end of the signal regulating module is connected to an input end of the radio frequency power amplifier, and the signal regulating module is configured to adjust at least one of an amplitude or a phase of a signal output by the delay module based on the regulation control signal;
wherein the transient response time determination method comprises:
acquiring a transient response time of the signal regulating module, a transient response time of signal amplitude processing of the signal amplitude and phase processing module, a transient response time of signal phase processing of the signal amplitude and phase processing module, a first transmission time, and a second transmission time; wherein the first transmission time is a signal delay time on an amplitude link trace from an input end of the signal amplitude and phase processing module to the control end of the signal regulating module, and the second transmission time is a signal delay time on a phase link trace from the input end of the signal amplitude and phase processing module to the control end of the signal regulating module;
determining a slowest transient response time of an amplitude link, a fastest transient response time of the amplitude link, a slowest transient response time of a phase link, and a fastest transient response time of the phase link based on the transient response time of the signal regulating module, the transient response time of the signal amplitude processing, the transient response time of the signal phase processing, the first transmission time, and the second transmission time;
determining an average transient response time of the amplitude link based on the slowest transient response time of the amplitude link and the fastest transient response time of the amplitude link;
determining an average transient response time of the phase link based on the slowest transient response time of the phase link and the fastest transient response time of the phase link; and
determining a delay time of the delay module based on the average transient response time of the amplitude link and the average transient response time of the phase link.

2. The transient response time determination method according to claim 1, wherein the signal regulating module comprises an adjustable attenuator and an adjustable phase shifter, an input end of the adjustable attenuator serves as the input end of the signal regulating module, an output end of the adjustable attenuator is connected to an input end of the adjustable phase shifter, and an output end of the adjustable phase shifter serves as the output end of the signal regulating module;
the signal amplitude and phase processing module comprises a signal amplitude detection unit, a signal amplitude regulating unit, a signal phase detection unit, and a signal phase regulating unit;
the signal amplitude detection unit is configured to detect the amplitude of the radio frequency input signal and the amplitude of the radio frequency output signal, and the signal amplitude regulating unit is configured to regulate a signal output by the signal amplitude detection unit;
the signal phase detection unit is configured to detect the phase of the radio frequency input signal and the phase of the radio frequency output signal, and the signal phase regulating unit is configured to regulate a signal output by the signal phase detection unit;
the signal amplitude detection unit, the signal amplitude regulating unit, and the adjustable attenuator form the amplitude link, and the signal phase detection unit, the signal phase regulating unit, and the adjustable phase shifter form the phase link; and
acquiring the transient response time of the signal regulating module, the transient response time of the signal amplitude processing of the signal amplitude and phase processing module, the transient response time of the signal phase processing of the signal amplitude and phase processing module, the first transmission time, and the second transmission time comprises:
acquiring a transient response time of the adjustable attenuator, a transient response time of the adjustable phase shifter, a transient response time of the signal amplitude detection unit, a transient response time of the signal amplitude regulating unit, a transient response time of the signal phase detection unit, a transient response time of the signal phase regulating unit, the first transmission time, and the second transmission time.

3. The transient response time determination method according to claim 2, wherein determining the slowest transient response time of the amplitude link, the fastest transient response time of the amplitude link, the slowest transient response time of the phase link, and the fastest transient response time of the phase link based on the transient response time of the signal regulating module, the transient response time of the signal amplitude processing, the transient response time of the signal phase processing, the first transmission time, and the second transmission time comprises:
obtaining the slowest transient response time of the amplitude link by summing up the transient response time of the adjustable attenuator, the transient response time of the signal amplitude detection unit, the transient response time of the signal amplitude regulating unit, and the first transmission time;
selecting a maximum value among the transient response time of the adjustable attenuator, the transient response time of the signal amplitude detection unit, and the transient response time of the signal amplitude regulating unit as a first transient response time;
obtaining the fastest transient response time of the amplitude link by summing up the first transient response time and the first transmission time;
obtaining the slowest transient response time of the phase link by summing up the transient response time of the adjustable phase shifter, the transient response time of the signal phase detection unit, the transient response time of the signal phase regulating unit, and the second transmission time;
selecting a maximum value among the transient response time of the adjustable phase shifter, the transient response time of the signal phase detection unit, and the transient response time of the signal phase regulating unit as a second transient response time; and
obtaining the fastest transient response time of the phase link by summing up the second transient response time and the second transmission time.

4. The transient response time determination method according to claim 1, wherein the signal amplitude and phase processing module comprises a signal amplitude detection unit, a signal amplitude regulating unit, a signal phase detection unit, a signal phase regulating unit, and a signal comprehensive weighting unit;
the signal amplitude detection unit is configured to detect the amplitude of the radio frequency input signal and the amplitude of the radio frequency output signal, and the signal amplitude regulating unit is configured to regulate a signal output by the signal amplitude detection unit;
the signal phase detection unit is configured to detect the phase of the radio frequency input signal and the phase of the radio frequency output signal, and the signal phase regulating unit is configured to regulate a signal output by the signal phase detection unit;
the signal comprehensive weighting unit is configured to further regulate a signal output by the signal amplitude regulating unit and a signal output by the signal phase regulating unit;
the signal amplitude detection unit, the signal amplitude regulating unit, the signal comprehensive weighting unit, and the signal regulating module form the amplitude link, and the signal phase detection unit, the signal phase regulating unit, the signal comprehensive weighting unit, and the signal regulating module form the phase link; and
acquiring the transient response time of the signal regulating module, the transient response time of the signal amplitude processing of the signal amplitude and phase processing module, the transient response time of the signal phase processing of the signal amplitude and phase processing module, the first transmission time, and the second transmission time comprises:
acquiring the transient response time of the signal regulating module, a transient response time of the signal amplitude detection unit, a transient response time of the signal amplitude regulating unit, a transient response time of the signal phase detection unit, a transient response time of the signal phase regulating unit, a transient response time of the signal comprehensive weighting unit, the first transmission time, and the second transmission time.

5. The transient response time determination method according to claim 4, wherein determining the slowest transient response time of the amplitude link, the fastest transient response time of the amplitude link, the slowest transient response time of the phase link, and the fastest transient response time of the phase link based on the transient response time of the signal regulating module, the transient response time of the signal amplitude processing, the transient response time of the signal phase processing, the first transmission time, and the second transmission time comprises:
obtaining the slowest transient response time of the amplitude link by summing up the transient response time of the signal regulating module, the transient response time of the signal amplitude detection unit, the transient response time of the signal amplitude regulating unit, the transient response time of the signal comprehensive weighting unit, and the first transmission time;
selecting a maximum value among the transient response time of the signal regulating module, the transient response time of the signal amplitude detection unit, the transient response time of the signal amplitude regulating unit, and the transient response time of the signal comprehensive weighting unit as a third transient response time;
obtaining the fastest transient response time of the amplitude link by summing up the third transient response time and the first transmission time;
obtaining the slowest transient response time of the phase link by summing up the transient response time of the signal regulating module, the transient response time of the signal phase detection unit, the transient response time of the signal phase regulating unit, the transient response time of the signal comprehensive weighting unit, and the second transmission time;
selecting a maximum value among the transient response time of the signal regulating module, the transient response time of the signal phase detection unit, the transient response time of the signal phase regulating unit, and the transient response time of the signal comprehensive weighting unit as a fourth transient response time; and
obtaining the fastest transient response time of the phase link by summing up the fourth transient response time and the second transmission time.

6. The transient response time determination method according to claim 1, after determining the delay time of the delay module based on the average transient response time of the amplitude link and the average transient response time of the phase link, further comprising:
determining a tolerance range of an average transient response time based on the average transient response time of the amplitude link, the average transient response time of the phase link, and the delay time of the delay module.

7. The transient response time determination method according to claim 6, wherein determining the tolerance range of the average transient response time based on the average transient response time of the amplitude link, the average transient response time of the phase link, and the delay time of the delay module comprises:
obtaining a first boundary value of the tolerance range of the average transient response time by subtracting the delay time of the delay module from the average transient response time of the amplitude link; and
obtaining a second boundary value of the tolerance range of the average transient response time by subtracting the delay time of the delay module from the average transient response time of the phase link;
wherein the first boundary value and the second boundary value are opposite numbers of each other.

8. (canceled)

9. An electronic device, comprising:
at least one processor, and
a memory configured to store at least one program;
wherein the at least one program, when executed by the at least one processor, causes the at least one processor to perform a transient response time determination method used to determine a transient response time of nonlinear correction of a radio frequency power amplifier in a nonlinear correction system;
wherein the transient response time determination method comprises:
acquiring a transient response time of a signal regulating module, a transient response time of signal amplitude processing of a signal amplitude and phase processing module, a transient response time of signal phase processing of the signal amplitude and phase processing module, a first transmission time, and a second transmission time; wherein the first transmission time is a signal delay time on an amplitude link trace from an input end of the signal amplitude and phase processing module to a control end of the signal regulating module, and the second transmission time is a signal delay time on a phase link trace from the input end of the signal amplitude and phase processing module to the control end of the signal regulating module;
determining a slowest transient response time of an amplitude link, a fastest transient response time of the amplitude link, a slowest transient response time of a phase link, and a fastest transient response time of the phase link based on the transient response time of the signal regulating module, the transient response time of the signal amplitude processing, the transient response time of the signal phase processing, the first transmission time, and the second transmission time;
determining an average transient response time of the amplitude link based on the slowest transient response time of the amplitude link and the fastest transient response time of the amplitude link;
determining an average transient response time of the phase link based on the slowest transient response time of the phase link and the fastest transient response time of the phase link; and
determining a delay time of a delay module based on the average transient response time of the amplitude link and the average transient response time of the phase link;
wherein a radio frequency input signal is coupled to an input end of the delay module, an output end of the delay module is connected to an input end of the signal regulating module, and the delay module is configured to delay and transmit the radio frequency input signal to the signal regulating module;
an output end of the signal amplitude and phase processing module is connected to the control end of the signal regulating module, and the signal amplitude and phase processing module is configured to generate a regulation control signal based on at least one of an amplitude or a phase of the radio frequency input signal and at least one of an amplitude or a phase of a radio frequency output signal; and
an output end of the signal regulating module is connected to an input end of the radio frequency power amplifier, and the signal regulating module is configured to adjust at least one of an amplitude or a phase of a signal output by the delay module based on the regulation control signal.

10. A non-transitory computer-readable storage medium storing a computer program that, when executed by a processor, implements a transient response time determination method used to determine a transient response time of nonlinear correction of a radio frequency power amplifier in a nonlinear correction system;
wherein the transient response time determination method comprises:
acquiring a transient response time of a signal regulating module, a transient response time of signal amplitude processing of a signal amplitude and phase processing module, a transient response time of signal phase processing of the signal amplitude and phase processing module, a first transmission time, and a second transmission time; wherein the first transmission time is a signal delay time on an amplitude link trace from an input end of the signal amplitude and phase processing module to a control end of the signal regulating module, and the second transmission time is a signal delay time on a phase link trace from the input end of the signal amplitude and phase processing module to the control end of the signal regulating module;
determining a slowest transient response time of an amplitude link, a fastest transient response time of the amplitude link, a slowest transient response time of a phase link, and a fastest transient response time of the phase link based on the transient response time of the signal regulating module, the transient response time of the signal amplitude processing, the transient response time of the signal phase processing, the first transmission time, and the second transmission time;
determining an average transient response time of the amplitude link based on the slowest transient response time of the amplitude link and the fastest transient response time of the amplitude link:
determining an average transient response time of the phase link based on the slowest transient response time of the phase link and the fastest transient response time of the phase link; and
determining a delay time of a delay module based on the average transient response time of the amplitude link and the average transient response time of the phase link;
wherein a radio frequency input signal is coupled to an input end of the delay module, an output end of the delay module is connected to an input end of the signal regulating module, and the delay module is configured to delay and transmit the radio frequency input signal to the signal regulating module;
an output end of the signal amplitude and phase processing module is connected to the control end of the signal regulating module, and the signal amplitude and phase processing module is configured to generate a regulation control signal based on at least one of an amplitude or a phase of the radio frequency input signal and at least one of an amplitude or a phase of a radio frequency output signal; and
an output end of the signal regulating module is connected to an input end of the radio frequency power amplifier, and the signal regulating module is configured to adjust at least one of an amplitude or a phase of a signal output by the delay module based on the regulation control signal.

11. An electronic device, comprising:
at least one processor, and
a memory configured to store at least one program;
wherein the at least one program, when executed by the at least one processor, causes the at least one processor to perform the transient response time determination method according to claim 2.

12. An electronic device, comprising:
at least one processor, and
a memory configured to store at least one program;
wherein the at least one program, when executed by the at least one processor, causes the at least one processor to perform the transient response time determination method according to claim 3.

13. An electronic device, comprising:
at least one processor, and
a memory configured to store at least one program;
wherein the at least one program, when executed by the at least one processor, causes the at least one processor to perform the transient response time determination method according to claim 4.

14. An electronic device, comprising:
at least one processor, and
a memory configured to store at least one program;
wherein the at least one program, when executed by the at least one processor, causes the at least one processor to perform the transient response time determination method according to claim 5.

15. An electronic device, comprising:
at least one processor, and
a memory configured to store at least one program;
wherein the at least one program, when executed by the at least one processor, causes the at least one processor to perform the transient response time determination method according to claim 6.

16. An electronic device, comprising:
at least one processor, and
a memory configured to store at least one program;
wherein the at least one program, when executed by the at least one processor, causes the at least one processor to perform the transient response time determination method according to claim 7.

17. A non-transitory computer-readable storage medium storing a computer program that, when executed by a processor, implements the transient response time determination method according to claim 2.

18. A non-transitory computer-readable storage medium storing a computer program that, when executed by a processor, implements the transient response time determination method according to claim 3.

19. A non-transitory computer-readable storage medium storing a computer program that, when executed by a processor, implements the transient response time determination method according to claim 4.

20. A non-transitory computer-readable storage medium storing a computer program that, when executed by a processor, implements the transient response time determination method according to claim 5.

21. A non-transitory computer-readable storage medium storing a computer program that, when executed by a processor, implements the transient response time determination method according to claim 6.
